(19) United States
(12) Patent Application Publication
(10) Pub. No.: US 2026/0190649 A1
(43) Pub. Date: Jul. 2, 2026

(54) Display Device

(71) Applicant: LG Display Co., Ltd., Seoul (KR)

(72) Inventors: Dongjoo Lee, Goyang-si (KR); Minsu Kim, Goyang-si (KR)

(21) Appl. No.: 19/432,760

(22) Filed: Dec. 24, 2025

(30) Foreign Application Priority Data
Dec. 31, 2024 (KR) 10-2024-0202022

(51) Int. Cl. H10K 59/122; H10K 59/131; H10K 59/80

(52) U.S. Cl. CPC H10K 59/122; H10K 59/131; H10K 59/80521

(57) ABSTRACT

According to an aspect of the present disclosure, a display device includes a substrate including a display area and a first non-display area adjacent to the display area, a light emitting element disposed on the substrate in the display area and including a first electrode, a light emitting layer disposed on the first electrode, and a second electrode disposed on the light emitting layer, and a deposition prevention pattern disposed on the substrate in the first non-display area. The second electrode being disposed to extend into the first non-display area and does not overlap with the deposition prevention pattern in the first non-display area. Accordingly, a narrow bezel may be implemented.

### CROSS-REFERENCE TO RELATED APPLICATIONS

This application claims the benefit and priority to Republic of Korea Patent Application No. 10-2024-0202022 filed on Dec. 31, 2024, in the Korean Intellectual Property Office, the entire disclosure of which is incorporated herein by reference for all purposes, as if fully set forth herein.

### TECHNICAL FIELD

The present disclosure relates to a display device, and more particularly, for example, without limitation, to a display device in which an adhesion between components is improved and a bezel is reduced.

### DESCRIPTION OF THE RELATED ART

As it enters the information age, the field of display devices that visually display electrical information signals is rapidly developing, and research is being conducted to develop performances such as thinning, weight reduction, and low power consumption for various display devices.

Representative display devices include a liquid crystal display (LCD), a field emission display (FED), an electro-wetting display (EWD), and an electroluminescent display device such as an organic light emitting display (OLED) or light emitting display (LED).

An electroluminescent display device such as an organic light emitting display device is a self-emitting display device and does not require a separate light source unlike a liquid crystal display device. Therefore, the electroluminescent display device can be manufactured to have a light weight and a small thickness. In addition, the electroluminescent display device is advantageous in terms of power consumption because the electroluminescent display device operates at a low voltage. Further, the electroluminescent display device is expected to be utilized in various fields because the electroluminescent display device is excellent in implementation of colors, response speeds, viewing angles, and contrast ratios (CRs).

The description provided in the background section should not be assumed to be prior art merely because it is mentioned in or associated with the background section. The background section may include information that describes one or more aspects of the subject technology.

### SUMMARY

An aspect of the present disclosure is to provide a display device in which an adhesion between components is improved.

An aspect of the present disclosure is to provide a display device in which film lifting defects due to weakened adhesion are improved.

An aspect of the present disclosure is to provide a display device capable of minimizing or reducing the penetration of impurities due to film lifting.

An aspect of the present disclosure is to provide a display device capable of implementing a narrow bezel.

Aspects of the present disclosure are not limited to the above-mentioned aspects, and other aspects, which are not mentioned above, can be clearly understood by those skilled in the art from the following descriptions.

Additional features and aspects of the disclosure are set forth in part in the description that follows and in part will become apparent from the description or may be learned by practice of the inventive concepts provided herein. Other features and aspects of the inventive concepts may be realized and attained by the structures pointed out in the present disclosure, or derivable therefrom, and the claims hereof as well as the appended drawings.

To achieve these and other aspects of the inventive concepts, as embodied and broadly described herein, a display device includes a substrate including a display area and a first non-display area adjacent to the display area, a light emitting element disposed on the substrate in the display area and including a first electrode, a light emitting layer disposed on the first electrode, and a second electrode disposed on the light emitting layer, and a deposition prevention pattern disposed on the substrate in the first non-display area. The second electrode is disposed to extend into the first non-display area and does not overlap with the deposition prevention pattern in the first non-display area. Accordingly, a narrow bezel may be implemented.

Further, a display device may include a substrate including a display area and a non-display area adjacent to the display area, a light emitting element disposed on the substrate in the display area including a cathode electrode, and a deposition pattern. The cathode may extend from the display area into the non-display area. The deposition pattern may be disposed in the non-display area between (i) a contact area where the cathode electrode contacts a conductive layer that is electrically connected to a power line and (ii) an edge of the non-display area, wherein the deposition prevention pattern does not overlap with either the cathode electrode or the power line in a plan view of the display device.

Other detailed matters of the embodiments are included in the detailed description and the drawings.

According to the exemplary embodiment of the present disclosure, the bezel may be minimized or reduced by using a difference in process margin between the deposition prevention pattern and the second electrode.

According to the exemplary embodiment of the present disclosure, a deposition prevention pattern requiring a relatively small process margin is disposed in the non-display area to adjust the arrangement area of the second electrode, thereby minimizing or reducing the bezel.

According to the exemplary embodiment of the present disclosure, it is possible to minimize or reduce the process margin required for connection between the second electrode and the power line by using the process method with improved precision.

According to the exemplary embodiment of the present disclosure, the second electrode is patterned using the deposition prevention pattern to improve adhesion between components disposed above and below the second electrode.

According to the exemplary embodiment of the present disclosure, the film lifting defects can be minimized or reduced by improving adhesion between the components.

According to the exemplary configuration of the present disclosure, the penetration of impurities due to film lifting may be minimized or reduced, and reliability may be improved.

According to the exemplary embodiment of the present disclosure, by minimizing or reducing a potential defect caused by film lifting, the lifespan of the display device may be improved, and the display device may be driven with low power in terms of reducing production energy.

The effects according to the present disclosure are not limited to the contents exemplified above, and more various effects are included in the present disclosure.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings, in which:

FIG. 1 is a schematic plan view of a display device according to an exemplary embodiment of the present disclosure.

FIG. 2 is an example cross-sectional view taken along line II-II′ in FIG. 1.

FIG. 3 is an example cross-sectional view taken along the line III-III′ of FIG. 1.

FIG. 4 is an example cross-sectional view taken along line IV-IV′ in FIG. 1.

FIG. 5 is an example cross-sectional view taken along line V-V′ in FIG. 1.

FIG. 6 is a cross-sectional view of a display device according to another exemplary embodiment of the present disclosure.

FIG. 7 is a cross-sectional view of a display device according to another exemplary embodiment of the present disclosure.

FIG. 8 is a cross-sectional view of a display device according to another exemplary embodiment of the present disclosure.

FIG. 9 is a schematic plan view of a display device according to still another exemplary embodiment of the present disclosure.

FIG. 10 is an enlarged plan view of display device according to still another exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION OF THE EMBODIMENT

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure and a method of achieving the advantages and features will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Any implementation described herein as an “example” is not necessarily to be construed as preferred or advantageous over other implementations.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more limiting term such as “only”. An element described in the singular form is intended to include a plurality of elements, and vice versa, unless the context clearly indicates otherwise.

In construing an element, the element is construed as including an ordinary error range or tolerance range although there is no explicit description of such an error or tolerance range.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

When an element or layer is disposed “on” another element or layer, another layer or another element may be interposed directly on the other element or therebetween.

Although the terms “first”, “second”, “A”, “B”, “(a)”, “(b)” and the like are used for describing various components, the essence, sequence, order, or number of these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

In the description of embodiments, when a structure is described as being positioned “on or above” or “under or below” another structure, this description should be construed as including a case in which the structures contact each other as well as a case in which a third structure is disposed therebetween. A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning, for example, consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, display devices according to various exemplary embodiments of the present disclosure will be described in detail with reference to accompanying drawings. Further, all the components of each display device according to all embodiments of the present disclosure are operatively coupled and configured.

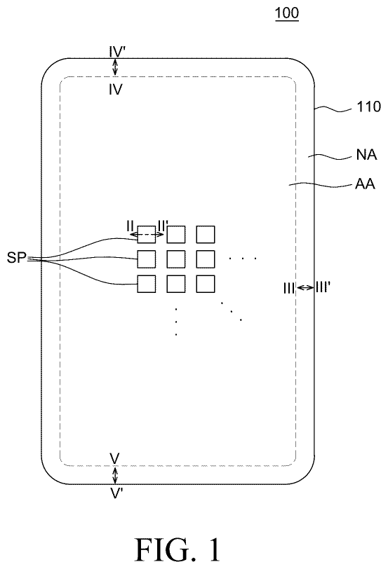

FIG. 1 is a schematic plan view of a display device according to an exemplary embodiment of the present disclosure.

Referring to FIG. 1, the display device 100 may include a substrate 110. The substrate 110 is a substrate which supports components disposed above the substrate 110 and may be an insulating substrate or a semiconductor substrate. The substrate 110 may include glass, plastic, a flexible polymer film, or the like. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer(COC), triacetylcellulose (TAC) film, polyvinyl alcohol (PVA) film, polyimide (PI) film, and polystyrene (PS), which is only an example and is not necessarily limited thereto. In addition, the substrate 110 may be made of a material including polymer or plastic, but is not limited thereto.

The substrate 110 may include a display area AA and a non-display area NA adjacent to the display area AA.

The display area AA is an area in which images are displayed in the display device 100. In the display area AA, a plurality of sub-pixels SP constituting a plurality of pixels and a circuit for driving the plurality of sub-pixels SP may be disposed. The plurality of sub-pixels SP is a minimum unit constituting the display area AA, and one or more sub-pixels SP may form one pixel. In each of the plurality of sub-pixels SP, a light emitting element, a thin film transistor for driving the light emitting element, and the like may be disposed. The plurality of light emitting elements may be differently defined depending on the type of display panel. For example, when the display panel is an organic light emitting display panel, the light emitting element may be an organic light emitting element (OLED).

In the display area AA, a plurality of wiring lines for transmitting various signals to the plurality of sub-pixels SP may be disposed. For example, the plurality of wiring lines may include a plurality of data lines which supplies a data voltage to each of the plurality of sub-pixels SP, a plurality of scan lines which supplies a scan signal to each of the plurality of sub-pixels SP, and the like. The plurality of scan lines may extend in one direction in the display area AA and may be connected to the plurality of sub-pixels SP, and the plurality of data lines may extend in a direction different from the one direction in the display area AA and may be connected to the plurality of sub-pixels SP. In addition, in the display area AA, a low potential power line, a high potential power line, a reference line, and the like may be further disposed, but are not limited thereto.

The non-display area NA may surround the display area AA. The non-display area NA is an area where an image is not displayed and may be defined as an area extending from the display area AA. In the non-display area NA, a link line and a pad electrode for transmitting a signal to the sub-pixel SP of the display area AA, or a driver IC, such as a gate driver IC or a data driver IC, may be disposed.

However, the non-display area NA may be located on a rear surface of the display device, for example, a surface on which the sub-pixels SP are not disposed or may be omitted, and is not limited as illustrated in the drawing.

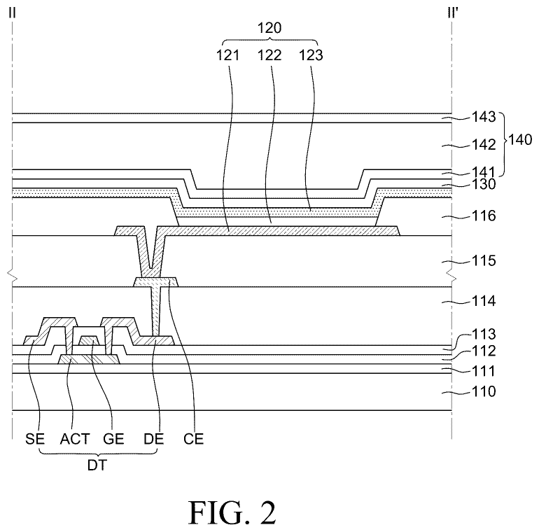

FIG. 2 is a cross-sectional view taken along line II-II′ in FIG. 1. Specifically, FIG. 2 is a cross-sectional view of one sub-pixel SP of the display device 100 according to the embodiment of the present disclosure.

Referring to FIG. 2, a buffer layer 111 may be disposed on the substrate 110. The buffer layer 111 may reduce penetration of moisture or impurities through the substrate 110. For example, the buffer layer 111 may be configured as a single layer or multilayer made of silicon oxide (SiOx) or silicon nitride (SiNx), but is not limited thereto. However, the buffer layer 111 may be omitted depending on the type of substrate 110 or the type of driving transistor DT, but is not limited thereto.

The driving transistor DT including an active layer ACT, a gate electrode GE, a source electrode SE, and a drain electrode DE may be disposed on the buffer layer 111.

First, the active layer ACT of the driving transistor DT may be disposed on the buffer layer 111. The active layer ACT may include a semiconductor material such as an oxide semiconductor, amorphous silicon, or polysilicon, but is not limited thereto. In addition, although not illustrated in the drawings, other transistors, such as a switching transistor, a sensing transistor, and an emission control transistor, other than the driving transistor DT, may be further disposed. The active layers of these transistors may also be made of a semiconductor material, such as an oxide semiconductor, amorphous silicon, or polysilicon, but are not limited thereto. In addition, the active layers of the transistors included in the pixel circuit, such as the driving transistor DT, the switching transistor, the sensing transistor, and the light emission control transistor, may include the same material or different materials.

The gate insulating layer 112 may be disposed on the active layer ACT. The gate insulating layer 112 is an insulating layer which electrically insulates the active layer ACT from the gate electrode GE and may be configured by a single layer or a double layer of silicon oxide (SiOx) or silicon nitride (SiNx), but is not limited thereto.

The gate electrode GE may be disposed on the gate insulating layer 112. The gate electrode GE may be configured by a conductive material such as copper (Cu), aluminum (Al), molybdenum (Mo), nickel (Ni), titanium (Ti), chromium (Cr), or an alloy thereof, but is not limited thereto.

The interlayer insulating layer 113 may be disposed on the gate electrode GE. Contact holes through which the source electrode SE and the drain electrode DE are connected to the active layer ACT may be formed in the interlayer insulating layer 113. The interlayer insulating layer 113 is an insulating layer which protects components below the interlayer insulating layer 113 and may be configured by a single layer or a double layer of silicon oxide (SiOx) or silicon nitride (SiNx), but is not limited thereto.

The source electrode SE and the drain electrode DE which are electrically connected to the active layer ACT may be disposed on the interlayer insulating layer 113. The drain electrode DE may be connected to the first electrode 121 of the light-emitting element 120 through the connection electrode CE. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto. It is to be noted that the source electrode SE and the drain electrode DE are not fixed, but may be interchanged with each other depending on the type of the thin film transistor and the voltage difference applied between the source electrode SE and the drain electrode DE. Thus, the source electrode SE and the drain electrode DE may be referred to as first and second electrodes respectively.

The first planarization layer 114 and the second planarization layer 115 may be disposed on the source electrode SE and the drain electrode DE. The first planarization layer 114 and the second planarization layer 115 may planarize an upper portion of the pixel circuit including the driving transistor DT. The first planarization layer 114 and the second planarization layer 115 may be configured by a single layer or a double layer, and for example, configured by benzocyclobutene or an acrylic-based organic material, but are not limited thereto. In addition, a contact hole through which the first electrode 121 of the light-emitting element 120 is connected to the connection electrode CE may be formed in the second planarization layer 115.

The connection electrode CE may be disposed on the first planarization layer 114. The connection electrode CE may electrically connect the drain electrode DE and the first electrode 121 of the light-emitting element 120 through a contact hole formed in the first planarization layer 114.

For example, the connection electrode CE may include the same material as the source electrode SE and the drain electrode DE, but is not limited thereto. In addition, the drain electrode DE and the first electrode 121 of the light-emitting element 120 may be directly connected with each other, and in this case, the connection electrode CE and the first planarization layer 114 may be omitted.

The first electrode 121 may be disposed on the second planarization layer 115. The first electrode 121 is a layer for supplying holes to the light emitting layer 122 and may be an anode. The first electrode 121 is a layer for supplying holes to the light emitting layer 122 and may include a conductive material having a high work function. The first electrode 121 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

A bank 116 may be disposed on the first electrode 121 and the second planarization layer 115. The bank 116 may cover an edge of the first electrode 121 of the light emitting element 120 to define an emission area. For example, the bank 116 may divide or define the plurality of sub-pixels SP. The bank 116 may include an insulating material to insulate the first electrodes 121 of the adjacent sub-pixels SP from each other. Further, the bank 116 may be configured by a black bank having a high light absorption rate to prevent or reduce color mixture between adjacent sub-pixels SP. For example, the bank 116 may include polyimide resin, acrylic resin, or benzocyclobutene (BCB) resin, but is not limited thereto. Alternatively, the bank 116 may include an inorganic insulating material such as silicon nitride, aluminum nitride, zirconium nitride, titanium nitride, hafnium nitride, tantalum nitride, silicon oxide, aluminum oxide, or titanium oxide, etc.

The light emitting layer 122 may be disposed on the first electrode 121. The light emitting layer 122 is a layer in which electrons and holes are combined to emit light.

The second electrode 123 may be disposed on the light emitting layer 122. The second electrode 123 is a layer for smoothly supplying electrons to the light emitting layer 122 and may be a cathode. Therefore, the second electrode 123 may include a metal material having a low work function. For example, the second electrode 123 may include a metal material selected from calcium (Ca), barium (Ba), aluminum (Al), silver (Ag), and an alloy including one or more of them, but is not limited thereto.

One or more of a hole injection layer, a hole transport layer, an electron transport layer, an electron injection layer, or the like may be further included to improve luminous efficiency of the light emitting element 120. For example, a hole injection layer and a hole transport layer may be disposed between the first electrode 121 and the light emitting layer 122, and an electron transport layer and an electron injection layer may be disposed between the light emitting layer 122 and the second electrode 123. Further, in the light emitting layer 122, a hole blocking layer or an electron blocking layer may be disposed to further improve the recombination efficiency of the holes and electrons.

The protective layer 130 may be disposed on the light emitting element 120 to prevent or reduce oxygen or moisture from penetrating into the light emitting element 120.

The encapsulation layer 140 may be disposed on the light emitting element 120. The encapsulation layer 140 may protect the light emitting element 120 from external moisture, oxygen, impact, and the like. The encapsulation layer 140 may have a multi-layered structure in which an inorganic layer made of an inorganic insulating material and an organic layer made of an organic material are stacked. The encapsulation layer 140, for example, may have a multi-layer structure in which at least one organic layer and at least two inorganic layers are alternately stacked, but is not limited thereto.

For example, the encapsulation layer 140 may have a triple-layered structure including a first inorganic encapsulation layer 141, an organic encapsulation layer 142, and a second inorganic encapsulation layer 143. In this case, the first inorganic encapsulation layer 141 and the second inorganic encapsulation layer 143 may independently include one or more selected from silicon nitride (SiNx), silicon oxide (SiOx), aluminum oxide (AlOx), and silicon oxynitride (SiON), but are not limited thereto.

In addition, the organic encapsulation layer 142 may include one or more selected from epoxy resin, polyimide resin, polyethylene resin, and silicon oxycarbide (SiOC), but is not limited thereto. A thickness difference due to the light emitting element 120 may be removed by the organic encapsulation layer 142. For example, an upper surface of the organic encapsulation layer 142 opposite to the substrate 110 may be a flat surface.

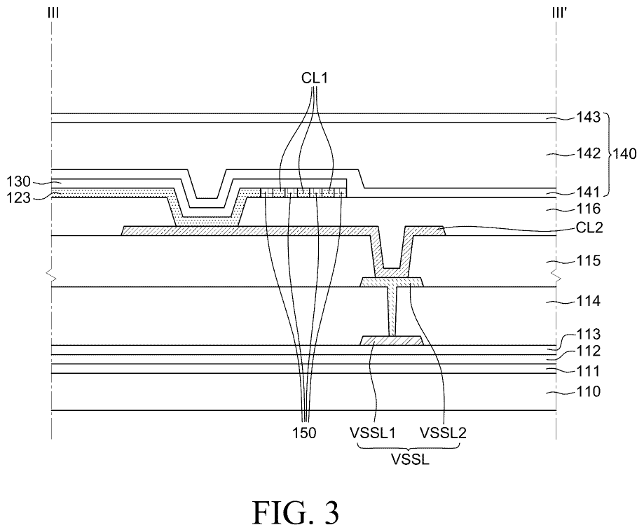

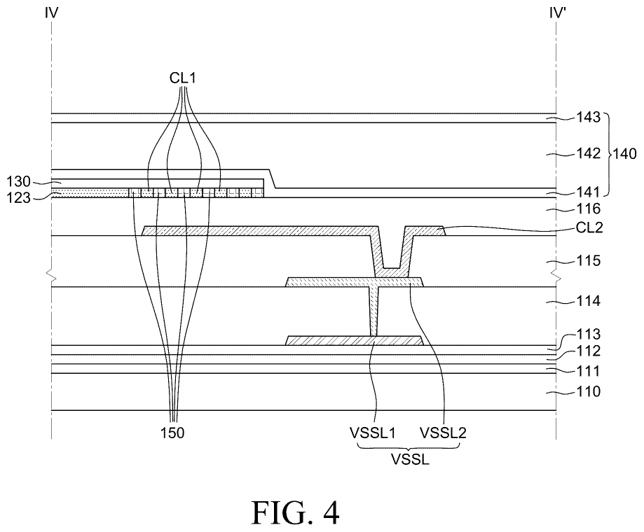

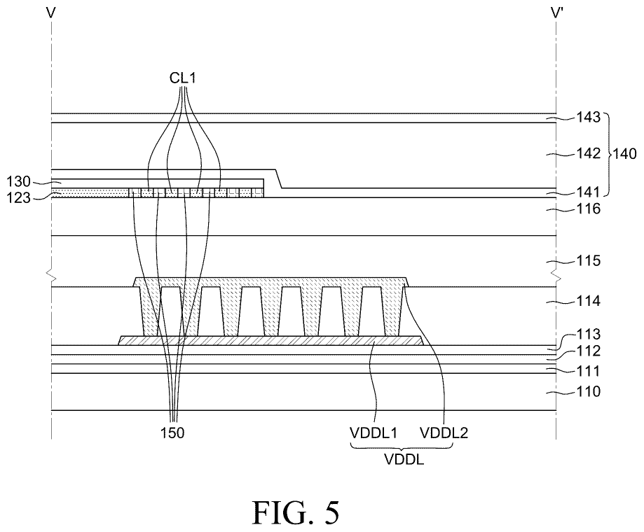

FIG. 3 is a cross-sectional view taken along the line III-III′ of FIG. 1. FIG. 4 is a cross-sectional view taken along line IV-IV′ in FIG. 1. FIG. 5 is a cross-sectional view taken along line V-V′ in FIG. 1. FIG. 3 is a cross-sectional view of a right portion of the non-display area NA, for example, a right bezel, and the left bezel may also be the same as the cross-sectional view of FIG. 3. FIG. 4 is a cross-sectional view of an upper portion of the non-display area NA, for example, an upper bezel. FIG. 5 is a cross-sectional view of a lower portion of the non-display area NA, for example, a lower bezel.

Referring to FIGS. 3 and 4, the low potential power line VSSL may be disposed on at least three of four sides of the non-display area NA. For example, in the low potential power line VSSL, the low potential power line VSSL may be disposed on the interlayer insulating layer 113 in the upper, left and right bezels. The low potential power line VSSL may be electrically connected to the light emitting element 120 together with the driving transistor DT to allow the light emitting element 120 to emit light.

The low potential power line VSSL may include a first low potential power line VSSL1 and a second low potential power line VSSL2 disposed on the first low potential power line VSSL1 and connected to the first low potential power line VSSL1. The first low potential power line VSSL1 may be disposed on the interlayer insulating layer 113. The first low potential power line VSSL1 may be disposed on the same layer as the source electrode SE and the drain electrode DE and may include the same material, but is not limited thereto.

The second low potential power line VSSL2 may be disposed on the first planarization layer 114 and connected to the first low potential power line VSSL1 through a contact hole of the first planarization layer 114. The second low potential power line VSSL2 may be disposed on the same layer as the connection electrode CE and made of the same material, but is not limited thereto.

Referring to FIG. 5, the high potential power line VDDL may be disposed on the interlayer insulating layer 113. The high potential power line VDDL may be disposed on one of four sides of the non-display area NA. For example, the high potential power line VDDL may transmit a high potential power voltage from the lower bezel to the pixel circuit of each of the plurality of sub-pixels SP.

The high potential power line VDDL may include a first high potential power line VDDL1 and a second high potential power line VDDL2 disposed on the first high potential power line VDDL1 and connected to the first high potential power line VDDL1.

The first high potential power line VDDL1 may be disposed on the interlayer insulating layer 113. The first high potential power line VDDL1 may be disposed on the same layer and made of the same material as the source electrode SE and the drain electrode DE, but is not limited thereto.

In addition, the second high potential power line VDDL2 may be disposed on the first planarization layer 114 and connected to the first high potential power line VDDL1 through a contact hole of the first planarization layer 114. The second high potential power line VDDL2 may be disposed on the same layer as the connection electrode CE and made of the same material, but is not limited thereto.

Referring back to FIGS. 3 and 4, the second conductive layer CL2 may be disposed on the second planarization layer 115. The second conductive layer CL2 may be disposed on at least three of four sides of the non-display area NA. For example, the second conductive layer CL2 may be disposed on the upper and left and right bezels.

The second conductive layer CL2 may connect the second electrode 123 with the low potential power line VSSL. For example, the second conductive layer CL2 may connect the low potential power line VSSL and the second electrode 123 on at least two of four sides of the non-display area NA. For example, the second conductive layer CL2 may be connected to the second low potential power line VSSL2 through the contact hole of the second planarization layer 115, but is not limited thereto.

For example, the second conductive layer CL2 may be disposed on the same layer as the first electrode 121 of the light emitting element 120 and may include the same material, but is not limited thereto.

Referring to FIGS. 3 to 5, the second electrode 123 of the light emitting element 120 may be disposed to extend to the non-display area NA. The second electrode 123 may be connected to the low potential power line VSSL in the non-display area NA. For example, the second electrode 123 may be connected to the low potential power line VSSL through the second conductive layer CL2 to be supplied with a low potential power voltage.

A plurality of deposition prevention patterns 150 may be disposed on the bank 116. The deposition prevention pattern 150 may perform a function of preventing or avoiding deposition of the second electrode 123 made of a metal material. Since the second electrode 123 made of a metal material is not deposited in the area in which the deposition prevention pattern 150 is disposed, the second electrode 123 may be disposed so as not to overlap with the deposition prevention pattern 150. Accordingly, an area of the second electrode 123 in the non-display area NA may be defined by the deposition prevention pattern 150. In addition, the deposition prevention pattern 150 may be referred to as a metal patterning layer (MPL) or cathode patterning material, but is not limited thereto. As shown in FIGS. 3 to 5, the deposition prevention pattern 150 is disposed on a same layer as the second electrode 123 and the first conductive layer CL1. In addition, the deposition prevention pattern 150 may include an organic material such as polyamide, polyimide, or acrylic resin, but is not limited thereto. In addition, as shown in FIGS. 3 to 5, the deposition prevention pattern 150 may be disposed to at least partially surround the display area AA.

The deposition prevention pattern 150 may be deposited using, for example, a fine metal mask (FMM). Accordingly, precise deposition may be possible, and thus, a required process margin may be relatively small compared to the second electrode 123 deposited using an open metal mask (OMM).

In addition, the deposition prevention pattern 150 may overlap with the second conductive layer CL2, the low potential power line VSSL, and the high potential power line VDDL, while the second electrode 123 disposed inside the deposition prevention pattern 150 may overlap only with the second conductive layer CL2 and may not overlap with the low potential power line VSSL and the high potential power line VDDL, but is not limited thereto.

In addition, the deposition prevention pattern 150 may include a plurality of holes. The plurality of holes may be formed by the forming or patterning of the deposition prevention pattern 150. Accordingly, the first conductive layer CL1 may be disposed in a plurality of holes from which the deposition prevention pattern 150 is removed. For example, since the first conductive layer CL1 is not deposited where the deposition prevention pattern 150 is disposed, the first conductive layer CL1 may be disposed only in a plurality of holes. Accordingly, the first conductive layer CL1 and the deposition prevention pattern 150 may be alternately disposed.

For example, the first conductive layer CL1 may be disposed on the same layer as the second electrode 123 and may include the same material, but is not limited thereto.

In addition, in FIGS. 3 to 5, it is illustrated that the end of the protective layer 130 matches the end of the deposition prevention pattern 150, but it is not limited thereto, and the arrangement area of the protective layer 130 may be designed in various ways.

The display device may include a display area in which pixels are disposed to display images, and a non-display area adjacent to the display area. In addition, the display device may include an electrode for supplying power to the pixel, and such an electrode may be disposed over the display area and the non-display area in various forms. For example, the cathode of the light emitting element supplied with power from the power line may be disposed over the display area and the non-display area of the substrate.

Accordingly, the cathode of the light emitting element may be in contact with other layers disposed above or below the cathode in the display area and the non-display area. At this time, when adhesion between the cathode and the layer in contact with the cathode is not sufficiently performed, it may lead to lifting of the cathode or the layer in contact with the cathode. Impurities may penetrate by such lifting, and the performance and lifespan of the display device may be degraded. In particular, since the cathode is one of the components with relatively weak adhesion to adjacent layers, a phenomenon of film lifting may occur more easily.

Accordingly, in the display device 100 according to the exemplary embodiment of the present disclosure, the deposition prevention pattern 150 is disposed in the non-display area NA so that the second electrode 123 of the light emitting element 120 is not disposed in the area in which the deposition prevention pattern 150 is disposed. For example, the deposition prevention pattern 150 may include a plurality of holes. Therefore, the second electrode 123 may be disposed inside the deposition prevention pattern 150, and the first conductive layer CL1 made of the same material as the second electrode 123 may be disposed only in the plurality of holes. Therefore, as compared with the case where the second electrode 123 is disposed over the entire surface of the non-display area NA, when the deposition prevention pattern 150 is disposed, the second electrode 123 is not disposed as much as the deposition prevention pattern 150 is disposed so that an area of the second electrode 123 disposed in the non-display area NA may be relatively reduced. Accordingly, it is possible to minimize or reduce a problem in which the adhesion between adjacent upper and lower layers is weakened by the second electrode 123. Accordingly, in the display device 100 according to the exemplary embodiment of the present disclosure, the penetration of impurities due to film lifting may be minimized or reduced, thereby improving the reliability of the display device 100.

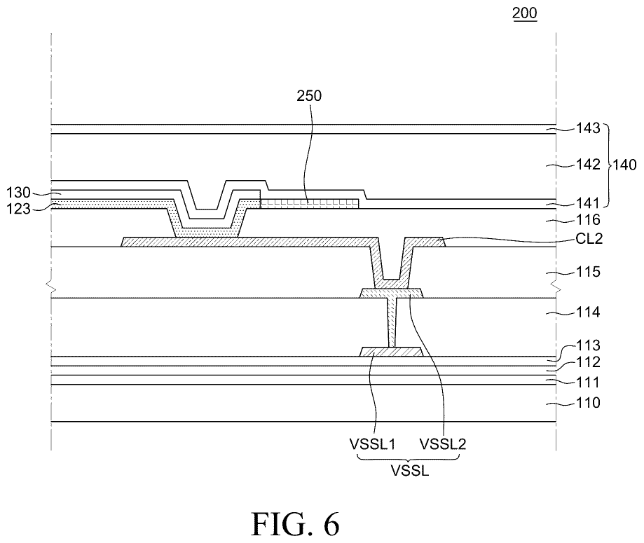

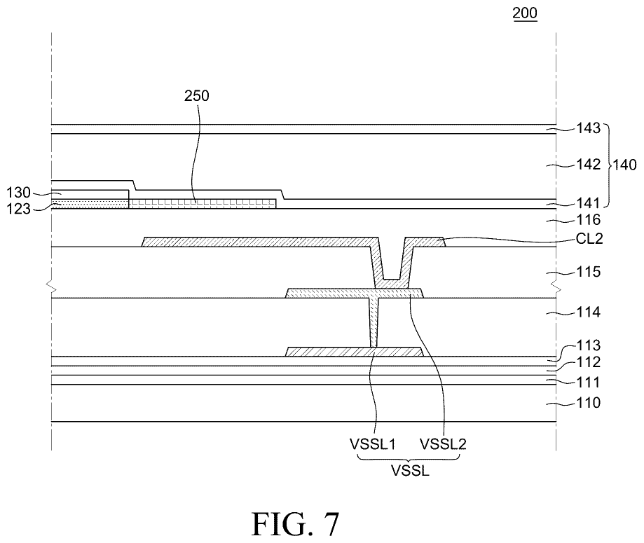

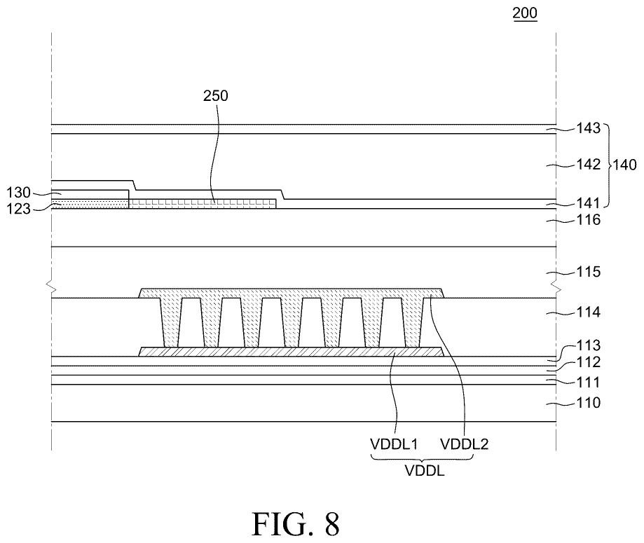

FIG. 6 is a cross-sectional view of a display device according to another exemplary embodiment of the present disclosure. FIG. 7 is a cross-sectional view of a display device according to another exemplary embodiment of the present disclosure. FIG. 8 is a cross-sectional view of a display device according to another exemplary embodiment of the present disclosure. A display device 200 of FIGS. 6 to 8 is substantially identical in configuration to the display device 100 of FIGS. 1 to 5, except for the presence or absence of the first conductive layer CL1 and the deposition prevention pattern 250. Therefore, repeated descriptions of the identical components will be omitted.

A plurality of deposition prevention patterns 250 may be disposed on the bank 116. The deposition prevention pattern 250 may perform a function of preventing or avoiding deposition of the second electrode 123 made of a metal material. Since the second electrode 123 made of a metal material is not deposited in the area in which the deposition prevention pattern 250 is disposed, the second electrode 123 may be disposed not to overlap with the deposition prevention pattern 250. As shown in FIGS. 6 to 8, the deposition prevention pattern 250 is disposed on a same layer as the second electrode 123. In addition, the deposition prevention pattern 250 may include an organic material such as polyamide, polyimide, or acrylic resin, but is not limited thereto.

For example, the deposition prevention pattern 250 may be continuously disposed without a separate hole. For example, compared with the case where the deposition prevention pattern 250 includes a plurality of holes, the deposition prevention pattern 250 may have a relatively large area. Therefore, the width or area of the second electrode 123 disposed in the non-display area NA may be further reduced.

In addition, the position of the deposition mask of the second electrode 123 may be adjusted in consideration of the arrangement position of the deposition prevention pattern 250. Therefore, the second electrode 123 may be disposed only before an area in which the deposition prevention pattern 250 is disposed. For example, the deposition prevention pattern 250 may be disposed outside the second electrode 123 to surround the end or outer edge of the second electrode 123. Therefore, the end of the deposition prevention pattern 250 may be in contact with the end or outer edge of the second electrode 123, but is not limited thereto. In other words, the second electrode 123 may be formed to extend from the display area AA to the deposition prevention pattern 250 and stops at the end of the deposition prevention pattern 250.

As described above, the cathode of the light emitting element supplied with power from the power line may be disposed over the display area and the non-display area of the substrate. For example, the cathode may be connected to the power line in the non-display area. Accordingly, during cathode deposition, a process margin required for connection between the cathode and the power line in the non-display area may be considered. For example, when the cathode is disposed throughout the display area and the non-display area, the cathode may be deposited using an open metal mask. Accordingly, the cathode may have a larger required process margin than the deposition prevention pattern deposited using a fine metal mask, which causes an increase in the bezel.

Accordingly, in the display device 200 according to another exemplary embodiment of the present disclosure, the deposition prevention pattern 250 may be disposed in the non-display area NA to adjust the arrangement area of the second electrode 123. Since the deposition prevention pattern 250 has a relatively small process margin, securing an area of the non-display area NA for disposing the deposition prevention pattern 250 may be minimized or reduced. Therefore, it is possible to minimize or reduce an unnecessary increase in bezel. Thereafter, during the deposition of the second electrode 123, the position of the deposition mask of the second electrode 123 may be adjusted in consideration of the placement position of the deposition prevention pattern 250. Therefore, as compared with the case where the deposition prevention pattern 250 is not disposed, the process margin required for the deposition of the second electrode 123 may be reduced. For example, in the display device 200 according to another exemplary embodiment of the present disclosure, the bezel is minimized or reduced by using the process margin difference between the second electrode 123 and the deposition prevention pattern 250, thereby improving the display quality.

In addition, in the display device 200 according to another exemplary embodiment of the present disclosure, the deposition prevention pattern 250 is disposed in the non-display area NA so that the second electrode 123 of the light emitting element 120 may not be disposed in the area in which the deposition prevention pattern 250 is disposed. Accordingly, compared to the case where the second electrode 123 is disposed over the entire surface of the non-display area NA, when the deposition prevention pattern 250 is disposed, the second electrode 123 is not disposed as much as the deposition prevention pattern 250 is disposed so that an area of the second electrode 123 disposed in the non-display area NA may be relatively reduced. Accordingly, it is possible to minimize or reduce a problem in which the adhesion between adjacent upper and lower layers is weakened by the second electrode 123. Accordingly, in the display device 200 according to another exemplary embodiment of the present disclosure, the penetration of impurities due to film lifting may be minimized or reduced, thereby improving the reliability of the display device 200.

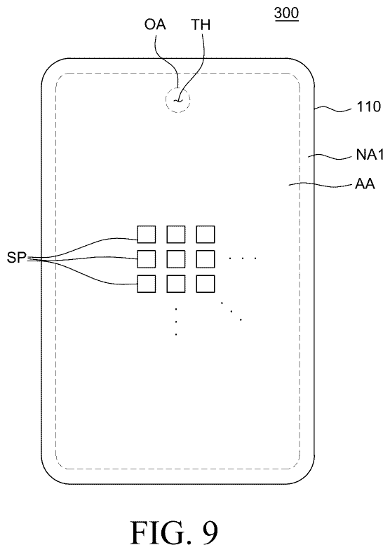

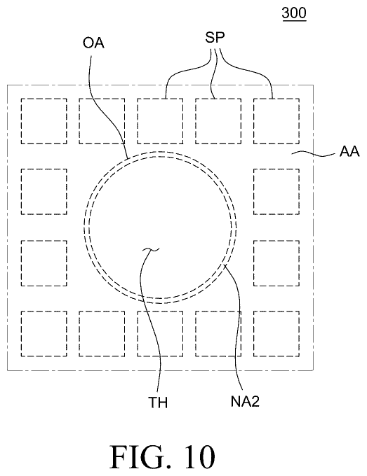

FIG. 9 is a schematic plan view of a display device according to still another exemplary embodiment of the present disclosure. FIG. 10 is an enlarged plan view of another display device of the present disclosure. A display device 100 of FIGS. 9 and 10 is substantially identical in configuration to the display device 100 of FIGS. 1 to 5 and the display device 200 of FIGS. 6 to 8, except for the presence or absence of an optical area OA. Therefore, repeated descriptions of the identical components will be omitted.

Referring to FIGS. 9 and 10, the optical area OA may be disposed in the display area AA. The optical area OA may be disposed between the plurality of sub-pixels SP in the display area AA. The optical area OA is an area in which an optical device such as a camera or a proximity sensor is disposed. Accordingly, the optical area OA may include a through hole TH passing through some components of the display device 100 to dispose the optical device. A through hole TH passing through the display panel including the substrate 110 may be formed to secure a space in which the optical device is disposed.

In addition, the inner bezel area, for example, the second non-display area NA2, may be disposed to surround the through hole TH. The sub-pixel SP is not disposed in the second non-display area NA2 and may be a non-display area like the through hole TH. The second non-display area NA2 may be disposed to block the penetration of cracks that may occur during the process of forming the through hole TH into the display area AA. Therefore, although not illustrated in the drawings, the second non-display area NA2 may include an uneven pattern for blocking moisture permeation and propagation of fine cracks introduced from the outside through the cutting line.

In addition, in order to be distinguished from the second non-display area NA2 which is an inner bezel area, the non-display area disposed to surround the display area AA may be referred to as a first non-display area NA1, or may also be referred to as an outer bezel area, but is not limited thereto.

In some display devices, a sub-pixel for image display may be disposed in the display area and the display area may include a light-transmitting area including a structure capable of transmitting light. This is a structure in which light transmittance is improved by forming a subpixel arrangement structure and a wiring arrangement structure differently, rather than forming a separate opening. In such a type of display device, a deposition prevention pattern can be used to increase light transmittance by removing the cathode.

In contrast, in the display device 300 according to still another exemplary embodiment of the present disclosure, the deposition prevention pattern may be disposed in the optical area OA including the through hole TH. For example, a deposition prevention pattern may be disposed not only in the first non-display area NA1, but also in the second non-display area NA2. Alternatively, the deposition prevention pattern may be disposed in the second non-display area NA2 instead of the first non-display area NA1. In this case, the deposition prevention pattern may be disposed in the second non-display area NA2 to surround the through hole TH, and the second electrode may be disposed to extend into the second non-display area NA2, and spaced apart from the through hole TH by at least the deposition prevention pattern. Therefore, like the first non-display area NA1, the weakening of the adhesion between the upper and lower layers by the second electrode may be minimized or reduced even in the second non-display area NA2. Accordingly, in the display device 300 according to still another exemplary embodiment of the present disclosure, the penetration of impurities due to film lifting may be minimized or reduced, thereby improving the reliability of the display device 300.

In particular, as illustrated in FIGS. 6 to 8, when the deposition prevention pattern does not include a plurality of holes and is continuously disposed, the second non-display area NA2 may be reduced. For example, the inner bezel may be minimized or reduced. In other words, in the display device 300 according to still another exemplary embodiment of the present disclosure, not only the first non-display area NA1, which is an external bezel, but also the second non-display area NA2, which is an internal bezel, may be minimized or reduced. Accordingly, the display quality of the display device 300 may be improved.

The exemplary embodiment of the present disclosure can also be described:

According to an aspect of the present disclosure, a display device includes a substrate including a display area and a first non-display area adjacent to the display area, a light-emitting element disposed on the substrate in the display area and including a first electrode, a light-emitting layer disposed on the first electrode, and a second electrode disposed on the light-emitting layer, and a deposition prevention pattern disposed on the substrate in the first non-display area. The second electrode being disposed to extend into the first non-display area and does not overlap with the deposition prevention pattern in the first non-display area.

The end of the deposition prevention pattern and the end of the second electrode may be in contact with each other in the first non-display area.

The deposition prevention pattern may be disposed outside the second electrode.

The deposition prevention pattern may be disposed to surround the end of the second electrode.

The deposition prevention pattern may be disposed to at least partially surround the display area.

The deposition prevention pattern may be disposed on the same layer as the second electrode and include a material different from that of the second electrode.

The deposition prevention pattern may include an organic material.

The display device may further include a first conductive layer disposed to be spaced apart from the second electrode in the first non-display area, the deposition prevention pattern may include a plurality of holes, and the first conductive layer may be disposed in the plurality of holes.

The deposition prevention pattern and the first conductive layer may be alternately disposed.

The first conductive layer may be disposed on the same layer as the second electrode and includes the same material.

The display device may further include a second conductive layer disposed on at least three of four sides of the first non-display area and disposed below the deposition prevention pattern so as to overlap with the deposition prevention pattern, and the second conductive layer may be connected to the second electrode on at least two sides of the first non-display area.

The second conductive layer may be disposed on the same layer as the first electrode and made of the same material.

The display device may further include a first power line disposed on one side of the first non-display area and a power line including a second power line disposed below the first power line and connected to the first power line, and the power line may be disposed to overlap with the deposition prevention pattern.

The second electrode may be disposed so as not to overlap with the power line.

An area of the second electrode in the first non-display area may be defined by the deposition prevention pattern.

The display device may further include a through hole disposed in the display area and a second non-display area surrounding the through hole, and the deposition prevention pattern may be further disposed to surround the through hole in the second non-display area.

According to another aspect of the present disclosure, a display device includes a substrate including a display area and a non-display area adjacent to the display area, a light-emitting element disposed on the substrate in the display area and including a first electrode, a light-emitting layer disposed on the first electrode, and a second electrode disposed on the light-emitting layer, and a deposition prevention pattern disposed on the substrate in the non-display area. The second electrode may be disposed to extend into the first non-display area, and an area of the second electrode in the non-display area is defined by the deposition prevention pattern.

According to yet another aspect of the present disclosure, a display device includes a substrate including a display area and a first non-display area adjacent to the display area, a light-emitting element disposed on the substrate in the display area and including a first electrode, a light-emitting layer disposed on the first electrode, and a second electrode disposed on the light-emitting layer, a through hole disposed within the display area, a second non-display area between the through hole and the display area; and a deposition prevention pattern disposed in the second non-display area to surround the through hole, wherein the second electrode is disposed to extend into the second non-display area, and spaced apart from the through hole by at least the deposition prevention pattern.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a display area and a first non-display area adjacent to the display area;
a light emitting element disposed on the substrate in the display area and including a first electrode, a light emitting layer disposed on the first electrode, and a second electrode disposed on the light emitting layer; and
a deposition prevention pattern disposed on the substrate in the first non-display area,
wherein the second electrode is disposed to extend into the first non-display area and does not overlap with the deposition prevention pattern in the first non-display area.

2. The display device according to claim 1, wherein an end of the deposition prevention pattern and an end of the second electrode are in contact with each other in the first non-display area.

3. The display device according to claim 1, wherein the deposition prevention pattern is disposed outside the second electrode.

4. The display device according to claim 1, wherein the deposition prevention pattern is disposed to surround an end of the second electrode.

5. The display device according to claim 1, wherein the deposition prevention pattern is disposed to at least partially surround the display area.

6. The display device according to claim 1, wherein the deposition prevention pattern is disposed on the same layer as the second electrode and include a material different from that of the second electrode.

7. The display device according to claim 6, wherein the deposition prevention pattern includes an organic material.

8. The display device according to claim 1, further comprising:
a first conductive layer disposed to be spaced apart from the second electrode in the first non-display area,
wherein the deposition prevention pattern includes a plurality of holes, and
the first conductive layer is disposed in the plurality of holes.

9. The display device according to claim 8, wherein the deposition prevention pattern and the first conductive layer are alternately disposed.

10. The display device according to claim 8, wherein the first conductive layer is disposed on the same layer as the second electrode and includes the same material.

11. The display device according to claim 1, further comprising:
a second conductive layer disposed on at least three of four sides of the first non-display area and disposed below the deposition prevention pattern so as to overlap with the deposition prevention pattern,
wherein the second conductive layer is connected to the second electrode on at least two sides of the first non-display area.

12. The display device according to claim 11, wherein the second conductive layer is disposed on the same layer as the first electrode and made of the same material.

13. The display device according to claim 1, further comprising:
a power line including a first power line disposed on one side of the first non-display area and a second power line disposed below the first power line and connected to the first power line,
wherein the power line is disposed so as to overlap with the deposition prevention pattern.

14. The display device according to claim 13, wherein the second electrode is disposed not to overlap with the power line.

15. The display device according to claim 1, wherein an area of the second electrode in the first non-display area is defined by the deposition prevention pattern.

16. The display device according to claim 1, further comprising:
a through hole disposed in the display area; and
a second non-display area surrounding the through hole,
wherein the deposition prevention pattern is further disposed in the second non-display area to surround the through hole.

17. A display device, comprising:
a substrate including a display area and a non-display area adjacent to the display area;
a light emitting element disposed on the substrate in the display area and including a first electrode, a light emitting layer disposed on the first electrode, and a second electrode disposed on the light emitting layer; and
a deposition prevention pattern disposed on the substrate in the non-display area,
wherein the second electrode is disposed to extend into the non-display area, and an area of the second electrode in the non-display area is defined by the deposition prevention pattern.

18. A display device, comprising:
a substrate including a display area and a first non-display area adjacent to the display area;
a light emitting element disposed on the substrate in the display area and including a first electrode, a light emitting layer disposed on the first electrode, and a second electrode disposed on the light emitting layer;
a through hole disposed within the display area;
a second non-display area between the through hole and the display area; and
a deposition prevention pattern disposed in the second non-display area to surround the through hole,
wherein the second electrode is disposed to extend into the second non-display area, and spaced apart from the through hole by at least the deposition prevention pattern.

19. A display device, comprising:
a substrate including a display area and a non-display area adjacent to the display area;
a light emitting element disposed on the substrate in the display area including a cathode electrode, the cathode electrode extending from the display area into the non-display area; and
a deposition prevention pattern disposed in the non-display area between (i) a contact area where the cathode electrode contacts a conductive layer that is electrically connected to a power line and (ii) an edge of the non-display area, wherein the deposition prevention pattern does not overlap with either the cathode electrode or the power line in a plan view of the display device.

20. The display device of claim 19, wherein the deposition prevention pattern is disposed between the contact area and the power line in the plan view of the display device, and does not overlap with the power line in the plan view of the display device.

21. The display device of claim 19, wherein the conductive layer is a first conductive layer, and wherein the deposition prevention pattern comprises a plurality of holes in which a second conductive layer is disposed.

22. The display device of claim 19, further comprising:
a protective layer disposed on the cathode electrode, the protective layer extending from the display area into the non-display area, wherein the deposition prevention pattern does not overlap with the protective layer in the plan view of the display device; and
an inorganic encapsulation layer disposed on the protective layer, the inorganic encapsulation layer in direct contact with the deposition prevention pattern.
